(19) United States
(12) Patent Application Publication
(10) Pub. No.: US 2024/0389288 A1
(43) Pub. Date: Nov. 21, 2024

(54) CAMERA MODULE AND ELECTRONIC DEVICE HAVING THE SAME

(71) Applicant: SAMSUNG ELECTRONICS CO., LTD., Suwon-si (KR)

(72) Inventors: Sukmin LEE, Suwon-si (KR); Manho KIM, Suwon-si (KR); Kihuk LEE, Suwon-si (KR)

(21) Appl. No.: 18/785,307

(22) Filed: Jul. 26, 2024

Related U.S. Application Data
(63) Continuation of application No. PCT/KR2023/002617, filed on Feb. 23, 2023.

(30) Foreign Application Priority Data
Mar. 7, 2022 (KR) 10-2022-0028747
Mar. 22, 2022 (KR) 10-2022-0035588

(51) Int. Cl. H05K 9/00; G03B 5/00; G03B 13/36; G03B 17/56; G03B 30/00

(52) U.S. Cl. CPC H05K 9/002; G03B 5/00; G03B 13/36; G03B 17/561; G03B 30/00; G03B 2205/0007; G03B 2205/0069

(57) ABSTRACT

An electronic device includes a housing defining an inner space, and a camera module fixed to the housing. The camera module includes a bracket fixed to the housing and including an accommodation space defined therein. Within the accommodation space is a lens and an actuator which adjusts a position of the lens, a shield can which covers the actuator, and an elastic structure which electrically connects the shield can to the bracket. The elastic structure includes an elastic portion which is between the shield can and the bracket and provides an elastic force to the shield can. The shield can and the bracket are electrically connected to each other at the elastic portion of the elastic structure.

### CROSS-REFERENCE TO RELATED APPLICATIONS

This application is a continuation application of International Application No. PCT/KR2023/002617 designating the United States, filed on Feb. 23, 2023, in the Korean Intellectual Property Receiving Office and claiming priority to Korean Patent Application No. 10-2022-0028747, filed on Mar. 7, 2022 and Korean Patent Application No. 10-2022-0035588, filed on Mar. 22, 2022, in the Korean Intellectual Property Office, the disclosures of which are incorporated by reference herein in their entireties.

### BACKGROUND

### (1) FIELD

Various embodiments of the present disclosure relate to a camera module and an electronic device including the same.

### (2) DESCRIPTION OF THE RELATED ART

An electronic device may include at least one camera module. The camera module may provide an autofocus function by moving a lens assembly in an optical axis direction. The camera module may provide an image stabilization function by moving the lens assembly. The image stabilization function may compensate for the shaking of an image due to external mechanical noise (e.g., vibration).

### SUMMARY

An actuator for adjusting a position of a lens assembly is provided in a camera module to implement an autofocus function and/or an image stabilization function. For example, the actuator may include a voice coil motor using an electromagnetic force. The actuator may be covered with a shield can to prevent a signal generated by the actuator from interfering with a signal generated by another electronic component. The shield can may be electrically connected to a bracket for the grounding of the shield can. However, a phenomenon may occur in which the shield can is not in electrical contact with the bracket due to manufacturing tolerance and/or assembly tolerance. To solve this, a method of attaching conductive tape or applying conductive epoxy between the shield can and the bracket has been developed. However, the conductive tape may be pushed or removed during an assembly process, and the conductive epoxy may require separate equipment, and considerate time may be required to cure the conductive epoxy.

According to various embodiments, a camera module having a structure for stably maintaining an electrical connection state between a shield can, a bracket, and an electronic device including the same may be provided.

According to various embodiments, a camera module which does not require separate additional equipment and is able to minimize an increase in process time and an electronic device including the same may be provided.

In various embodiments, an electronic device 301 includes a housing 310 configured to form an exterior of the electronic device 301, a support member 320 disposed in an inner space of the housing 310, and a camera module 400 fixedly connected to the support member 320, where the camera module 400 includes a lens assembly 410, a printed circuit board (PCB) 420 including an image sensor 421, an actuator 430 configured to adjust a position of the lens assembly 410, a shield can 440 positioned to cover at least a portion of the actuator 430, a bracket 450 including an accommodation space 451 enclosing the shield can 440 and configured to fix the camera module 400 to the support member 320, and an elastic structure 460 of which at least a portion is connected to the bracket 450 to be positioned between the shield can 440 and the bracket 450 and which is configured to generate an elastic force which presses the shield can 440 in one direction in the accommodation space 451, and the shield can 440 is electrically connected to the bracket 450 by the elastic structure 460.

In various embodiments, the camera module 400 includes the lens assembly 410, the PCB 420 including the image sensor 421, the actuator 430 configured to adjust a position of the lens assembly 410, the shield can 440 positioned to cover at least a portion of the actuator 430, the bracket 450 including the accommodation space 451 enclosing the shield can 440 and configured to fix the camera module 400 to the electronic device 301, and the elastic structure 460 of which at least a portion is connected to the bracket 450 to be positioned between the shield can 440 and the bracket 450 and which is configured to generate an elastic force which presses the shield can 440 in one direction in the accommodation space 451, and the shield can 440 is electrically connected to the bracket 450 by the elastic structure 460.

In various embodiments, the electronic device 301 includes the housing 310 configured to form an exterior of the electronic device 301, the support member 320 disposed in an inner space of the housing 310, and the camera module 400 fixedly connected to the support member 320, where the camera module 400 includes the lens assembly 410, the PCB 420 including the image sensor 421, the actuator 430 configured to adjust a position of the lens assembly 410, the shield can 440 positioned to cover at least a portion of the actuator 430, the bracket 450 including the accommodation space 451 enclosing the shield can 440 and configured to fix the camera module 400 to the support member 320, and the elastic structure 460 of which at least a portion is connected to the bracket 450 to be positioned between the shield can 440 and the bracket 450, which is configured to generate an elastic force which presses the shield can 440 in one direction in the accommodation space 451, and which is formed of a conductive and non-magnetic material, the bracket 450 includes at least one side wall 452 forming the accommodation space 451, the elastic structure 460 is engaged with the side wall 452 of the bracket 450, the shield can 440 is electrically connected to the bracket 450 by the elastic structure 460, a state in which an outer side surface 440a of the shield can 440 is in contact with an inner side surface 450a of the bracket 450 is maintained, a first ground path R1 is formed by contact between the outer side surface 450a of the shield can 440 and the inner side surface 450a of the bracket 450, and a second ground path R2 is formed by mutual contact between the shield can 440, the elastic structure 460, and the bracket 450.

According to various embodiments, an electrical connection state between a shield can and a bracket may be stably maintained.

According to various embodiments, a position of a shield can may be aligned in one direction in a bracket.

According to various embodiments, separate additional equipment may not be required and an increase in process time may be minimized.

The effects of the camera module and electronic device according to various embodiments are not limited to the above-mentioned effects, and other unmentioned effects can be clearly understood from the following description by one of ordinary skill in the art.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram of an electronic device in a network environment according to various embodiments.

FIG. 2 is a block diagram of an example of a camera module according to various embodiments.

FIG. 3A is a front perspective view of an electronic device according to various embodiments.

FIG. 3B is a rear perspective view of an electronic device according to various embodiments.

FIG. 3C is an exploded perspective view of an electronic device according to various embodiments.

FIG. 4A is a perspective view of a camera module according to an embodiment.

FIG. 4B is an exploded perspective view of a camera module according to an embodiment.

FIG. 4C is a partial perspective view of a side wall of a bracket according to an embodiment.

FIG. 4D is a perspective view of an elastic structure according to an embodiment.

FIG. 4E is a perspective view of a process of engaging an elastic structure with a bracket in an embodiment.

FIG. 4F is a perspective view of a state in which an elastic structure is engaged with a bracket in an embodiment.

FIG. 4G is a bottom view of a state in which an elastic structure is engaged with a bracket in an embodiment.

FIG. 4H is a cross-sectional side view of a camera module according to an embodiment.

FIG. 4I is a partial perspective view of a side wall of a bracket according to an embodiment.

FIG. 4J is a perspective view of an elastic structure according to an embodiment.

FIG. 4K is a cross-sectional side view of a state in which an elastic structure is engaged with a bracket in an embodiment.

FIG. 4L is a partial cross-sectional side view of a state in which an elastic structure is engaged with a bracket and a shield can is inserted into an accommodation space in an embodiment.

FIG. 5A is a partial perspective view of a side wall of a bracket according to an embodiment.

FIG. 5B is a perspective view of an elastic structure according to an embodiment.

FIG. 5C is a cross-sectional side view of a process of engaging an elastic structure with a bracket in an embodiment.

FIG. 5D is a cross-sectional side view of a state in which an elastic structure is engaged with a bracket in an embodiment.

FIG. 5E is a cross-sectional side view of a camera module according to an embodiment.

### DETAILED DESCRIPTION

Hereinafter, embodiments will be described in detail with reference to the accompanying drawings. When describing the embodiments with reference to the accompanying drawings, like reference numerals refer to like elements and a repeated description related thereto will be omitted.

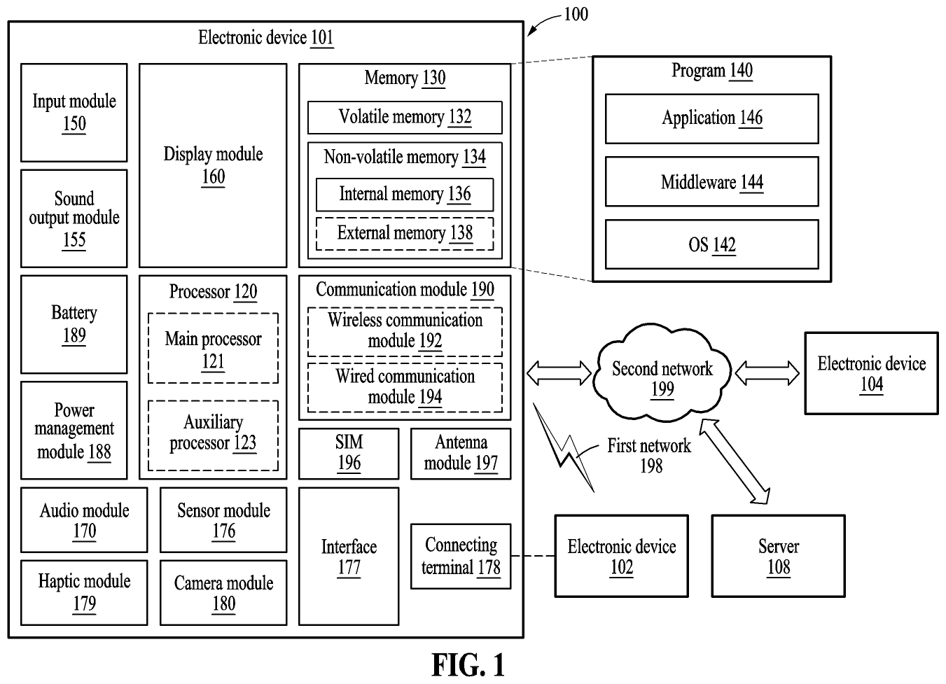

FIG. 1 is a block diagram illustrating an electronic device 101 in a network environment 100 according to an embodiment. Referring to FIG. 1, the electronic device 101 in the network environment 100 may communicate with an electronic device 102 via a first network 198 (e.g., a short-range wireless communication network), or communicate with at least one of an electronic device 104 or a server 108 via a second network 199 (e.g., a long-range wireless communication network). According to one embodiment, the electronic device 101 may communicate with the electronic device 104 via the server 108. According to one embodiment, the electronic device 101 may include a processor 120, a memory 130, an input module 150, a sound output module 155, a display module 160, an audio module 170, and a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one (e.g., the connecting terminal 178) of the above components may be omitted from the electronic device 101, or one or more other components may be added in the electronic device 101. In some embodiments, some (e.g., the sensor module 176, the camera module 180, or the antenna module 197) of the components may be integrated as a single component (e.g., the display module 160).

The processor 120 may execute, for example, software (e.g., a program 140) to control at least one other component (e.g., a hardware or software component) of the electronic device 101 connected to the processor 120, and may perform various data processing or computation. According to one embodiment, as at least a portion of data processing or computation, the processor 120 may store a command or data received from another component (e.g., the sensor module 176 or the communication module 190) in a volatile memory 132, process the command or the data stored in the volatile memory 132, and store resulting data in a non-volatile memory 134. According to one embodiment, the processor 120 may include a main processor 121 (e.g., a central processing unit (CPU) or an application processor (AP)) or an auxiliary processor 123 (e.g., a graphics processing unit (GPU), a neural processing unit (NPU), an image signal processor (ISP), a sensor hub processor, or a communication processor (CP)) which is operable independently of, or in conjunction with the main processor 121. For example, when the electronic device 101 includes the main processor 121 and the auxiliary processor 123, the auxiliary processor 123 may be adapted to consume less power than the main processor 121 or to be specific to a specified function. The auxiliary processor 123 may be implemented separately from the main processor 121 or as a part of the main processor 121.

The auxiliary processor 123 may control at least some of functions or states related to at least one (e.g., the display module 160, the sensor module 176, or the communication module 190) of the components of the electronic device 101, instead of the main processor 121 while the main processor 121 is in an inactive (e.g., sleep) state or along with the main processor 121 while the main processor 121 is in an active state (e.g., executing an application). According to one embodiment, the auxiliary processor 123 (e.g., an ISP or a CP) may be implemented as a portion of another component (e.g., the camera module 180 or the communication module 190) which is functionally related to the auxiliary processor 123. According to one embodiment, the auxiliary processor 123 (e.g., an NPU) may include a hardware structure specified for artificial intelligence (AI) model processing. An AI model may be generated by machine learning. Such learning may be performed by, for example, the electronic device 101 in which artificial intelligence is performed, or performed via a separate server (e.g., the server 108). Learning algorithms may include, but are not limited to, for example, supervised learning, unsupervised learning, semi-supervised learning, or reinforcement learning. The AI model may include a plurality of artificial neural network layers. An artificial neural network may include, for example, a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more thereof, but is not limited thereto. The AI model may additionally or alternatively include a software structure other than the hardware structure.

The memory 130 may store various data used by at least one component (e.g., the processor 120 or the sensor module 176) of the electronic device 101. The various pieces of data may include, for example, software (e.g., the program 140) and input data or output data for a command related thereto. The memory 130 may include the volatile memory 132 or the non-volatile memory 134.

The program 140 may be stored as software in the memory 130 and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output a sound signal to the outside of the electronic device 101. The sound output module 155 may include, for example, a speaker or a receiver. The speaker may be used for general purposes, such as playing multimedia or playing record. The receiver may be used to receive an incoming call. According to one embodiment, the receiver may be implemented separately from the speaker or as a part of the speaker.

The display module 160 may visually provide information to the outside (e.g., a user) of the electronic device 101. The display module 160 may include, for example, a control circuit for controlling a display, a hologram device, or a projector and control circuitry to control a corresponding one of the display, the hologram device, and the projector. According to one embodiment, the display module 160 may include a touch sensor adapted to sense a touch, or a pressure sensor adapted to measure an intensity of a force incurred by the touch.

The audio module 170 may convert a sound into an electrical signal or vice versa. According to one embodiment, the audio module 170 may obtain the sound via the input module 150 or output the sound via the sound output module 155 or an external electronic device (e.g., an electronic device 102 such as a speaker or a headphone) directly or wirelessly connected to the electronic device 101.

The sensor module 176 may detect an operational state (e.g., power or temperature) of the electronic device 101 or an environmental state (e.g., a state of a user) external to the electronic device 101, and generate an electrical signal or data value corresponding to the detected state. According to one embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., by wire) or wirelessly. According to an embodiment, the interface 177 may include, for example, a high-definition multimedia interface (HDMI), a universal serial bus (USB) interface, a secure digital (SD) card interface, or an audio interface.

The connecting terminal 178 may include a connector via which the electronic device 101 may be physically connected to an external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or an electrical stimulus which may be recognized by a user via his or her tactile sensation or kinesthetic sensation. According to one embodiment, the haptic module 179 may include, for example, a motor, a piezoelectric element, or an electric stimulator.

The camera module 180 may capture a still image and moving images. According to an embodiment, the camera module 180 may include one or more lenses, image sensors, ISPs, or flashes.

The power management module 188 may manage power supplied to the electronic device 101. According to an embodiment, the power management module 188 may be implemented as, for example, at least a part of a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors which are operable independently of the processor 120 (e.g., an AP) and which support a direct (e.g., wired) communication or a wireless communication. According to one embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module, or a power line communication (PLC) module). A corresponding one of these communication modules may communicate with the external electronic device 104 via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., a LAN or a wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the SIM 196.

The wireless communication module 192 may support a 5G network after a 4G network, and a next-generation communication technology, e.g., a new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., a mmWave band) to achieve, e.g., a high data transmission rate. The wireless communication module 192 may support various technologies for securing performance on a high-frequency band, such as, e.g., beamforming, massive multiple-input and multiple-output (MIMO), full dimensional MIMO (FD-MIMO), an array antenna, analog beam-forming, or a large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to one embodiment, the antenna module 197 may include a plurality of antennas (e.g., array antennas). In such a case, at least one antenna appropriate for a communication scheme used in a communication network, such as the first network 198 or the second network 199, may be selected by, for example, the communication module 190 from the plurality of antennas. The signal or power may be transmitted or received between the communication module 190 and the external electronic device via the at least one selected antenna. According to one embodiment, another component (e.g., a radio frequency integrated circuit (RFIC)) other than the radiating element may be additionally formed as a part of the antenna module 197.

According to various embodiments, the antenna module 197 may form a mmWave antenna module. According to an embodiment, the mmWave antenna module may include a PCB, an RFIC disposed on a first surface (e.g., a bottom surface) of the PCB or adjacent to the first surface and capable of supporting a designated a high-frequency band (e.g., the mmWave band), and a plurality of antennas (e.g., array antennas) disposed on a second surface (e.g., a top or a side surface) of the PCB, or adjacent to the second surface and capable of transmitting or receiving signals in the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the external electronic devices 102 and 104 may be a device of the same type as or a different type from the electronic device 101. According to one embodiment, all or some of operations to be executed by the electronic device 101 may be executed at one or more of the external electronic devices 102, 104, and 108. For example, if the electronic device 101 needs to perform a function or a service automatically, or in response to a request from a user or another device, the electronic device 101, instead of, or in addition to, executing the function or the service, may request one or more external electronic devices to perform at least part of the function or the service. The one or more external electronic devices receiving the request may perform the at least part of the function or the service requested, or an additional function or an additional service related to the request, and may transfer an outcome of the performing to the electronic device 101. The electronic device 101 may provide the result, with or without further processing the result, as at least part of a response to the request. To this end, cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., a smart home, a smart city, a smart car, or healthcare) based on 5G communication technology or IoT-related technology.

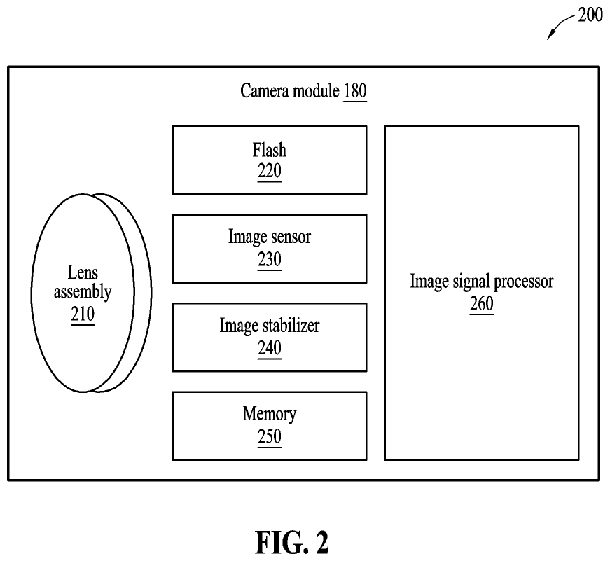

FIG. 2 is a block diagram 200 of an example of a camera module 180 according to various embodiments. Referring to FIG. 2, the camera module 180 may include a lens assembly 210, a flash 220, an image sensor 230, an image stabilizer 240, a memory 250 (e.g., a buffer memory), or an ISP 260. The lens assembly 210 may collect light reflected by an object which is a target of which an image is to be captured. The lens assembly 210 may include one or more lenses. According to an embodiment, the camera module 180 may include a plurality of lens assemblies 210. In this case, the camera module 180 may constitute, for example, a dual camera, a 360-degree camera, or a spherical camera. A portion of the lens assemblies 210 may have the same lens properties (e.g., an angle of view, a focal length, an auto focus, an f number, or an optical zoom), or at least one lens assembly may have one or more lens properties which are different from those of another lens assembly. The lens assembly 210 may include, for example, a wide-angle lens or a telephoto lens.

The flash 220 may emit light to be used to enhance light emitted or reflected from the object. According to an embodiment, the flash 220 may include one or more light-emitting diodes (LEDs) (e.g., a red-green-blue (RGB) LED, a white LED, an infrared (IR) LED, or an ultraviolet (UV) LED), or a xenon lamp. The image sensor 230 may obtain an image corresponding to the object by converting light, which is emitted or reflected from the object and is transmitted through the lens assembly 210, into an electrical signal. According to an embodiment, the image sensor 230 may include, for example, one image sensor selected from among image sensors having different properties, such as, for example, an RGB sensor, a black and white (BW) sensor, an IR sensor, or a UV sensor, a plurality of image sensors having the same property, or a plurality of image sensors having different properties. Each image sensor included in the image sensor 230 may be implemented using, for example, a charged coupled device (CCD) sensor or a complementary metal-oxide-semiconductor (CMOS) sensor.

The image stabilizer 240 may move at least one lens included in the lens assembly 210 or the image sensor 230 in a specific direction, or control an operation characteristic (e.g., adjust the read-out timing) of the image sensor 230, in response to a movement of the camera module 180 or the electronic device 101 including the camera module 180. This may compensate for at least a portion of a negative effect of the movement on an image to be captured. According to an embodiment, the image stabilizer 240 may sense such a movement of the camera module 180 or the electronic device 101 using a gyro sensor (not shown) or an acceleration sensor (not shown) disposed inside or outside the camera module 180. According to an embodiment, the image stabilizer 240 may be implemented as, for example, an optical image stabilizer. The memory 250 may temporarily store therein at least a portion of the image obtained through the image sensor 230 for a subsequent image processing operation. For example, when image acquisition is delayed by a shutter or a plurality of images is obtained at a high speed, an obtained original image (e.g., a Bayer-patterned image or a high-resolution image) may be stored in the memory 250, and a copy image (e.g., a low-resolution image) corresponding the original image may be previewed through the display module 160. Subsequently, when a specified condition (e.g., a user input or a system command) is satisfied, at least a portion of the original image stored in the memory 250 may be obtained and processed by, for example, the ISP 260. According to an embodiment, the memory 250 may be configured as at least part of the memory 130 or as a separate memory operated independently of the memory 130.

The ISP 260 may perform one or more image processing operations on an image obtained through the image sensor 230 or an image stored in the memory 250. The image processing operations may include, for example, depth map generation, three-dimensional (3D) modeling, panorama generation, feature point extraction, image synthesis, or image compensation (e.g., noise reduction, resolution adjustment, brightness adjustment, blurring, sharpening, or softening. Additionally or alternatively, the ISP 260 may control at least one of the components (e.g., the image sensor 230) included in the camera module 180 (e.g., control an exposure time, control a read-out timing, or the like). The image processed by the ISP 260 may be stored again in the memory 250 for further processing or may be provided to an external component (e.g., the memory 130, the display module 160, the electronic device 102, the electronic device 104, or the server 108) of the camera module 180. According to an embodiment, the ISP 260 may be configured as at least part of the processor 120 or as a separate processor operated independently of the processor 120. When the ISP 260 is configured as a processor separate from the processor 120, at least one image processed by the ISP 260 may be displayed as it is without a change or be displayed through the display module 160 after additional image processing is performed by the processor 120.

According to an embodiment, the electronic device 101 may include a plurality of camera modules 180 having different properties or functions. In this case, for example, at least one of the plurality of camera modules 180 may be a wide-angle camera, and at least another one of the plurality of camera modules 180 may be a telephoto camera. Similarly, at least one of the plurality of camera modules 180 may be a front camera, and at least another one of the plurality of camera modules 180 may be a rear camera.

The electronic device, according to embodiments, may be one of various types of electronic devices. The electronic device may include, for example, a portable communication device (e.g., a smartphone), a computer device, a portable multimedia device, a portable medical device, a camera, a wearable device, or a home appliance device. According to an embodiment of the present disclosure, the electronic device is not limited to those described above.

It should be appreciated that various example embodiments of the present disclosure and the terms used therein are not intended to limit the technological features set forth herein to particular embodiments and include various changes, equivalents, or replacements for a corresponding embodiment. In connection with the description of the drawings, like reference numerals may be used for similar or related components. Within the Figures and the text of the disclosure, a reference number indicating a singular form of an element may also be used to reference a plurality of the singular element.

It is to be understood that a singular form of a noun corresponding to an item may include one or more of the things, unless the relevant context clearly indicates otherwise. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. As used herein, “A or B”, “at least one of A and B”, “at least one of A or B”, “A, B or C”, “at least one of A, B and C”, and “A, B, or C,” each of which may include any one of the items listed together in the corresponding one of the phrases, or all possible combinations thereof. “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Terms such as “first”, “second”, or “first” or “second” may simply be used to distinguish the component from other components in question, and may refer to components in other aspects (e.g., importance or order) is not limited.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., by wire), wirelessly, or via a third element.

As used in connection with embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to one embodiment, the module may be implemented in a form of an application-specific integrated circuit (ASIC).

Embodiments as set forth herein may be implemented as software (e.g., the program 140) including one or more of instructions which are stored in a storage medium (e.g., an internal memory 136 or an external memory 138) which is readable by a machine (e.g., the electronic device 101). For example, a processor (e.g., the processor 120) of the machine (e.g., the electronic device 101) may invoke at least one of the one or more instructions stored in the storage medium and execute it. This allows the machine to be operated to perform at least one function according to the at least one instruction invoked. The one or more instructions may include code generated by a compiler or code executable by an interpreter. The machine-readable storage medium may be provided in the form of a non-transitory storage medium. Here, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments disclosed herein may be included and provided in a computer program product. The computer program product may be traded as a product between a seller and a buyer. The computer program product may be distributed in the form of a machine-readable storage medium (e.g., compact disc read-only memory (CD-ROM)), or be distributed (e.g., downloaded or uploaded) online via an application store (e.g., PlayStore™), or between two user devices (e.g., smartphones) directly. If distributed online, at least part of the computer program product may be temporarily generated or at least temporarily stored in the machine-readable storage medium, such as memory of the manufacturer's server, a server of the application store, or a relay server.

According to embodiments, each component (e.g., a module or a program) of the above-described components may include a single entity or multiple entities, and some of the multiple entities may be separately disposed in different components. According to embodiments, one or more of the above-described components may be omitted, or one or more other components may be added. Alternatively or additionally, a plurality of components (e.g., modules or programs) may be integrated into a single component. In such a case, according to embodiments, the integrated component may still perform one or more functions of each of the plurality of components in the same or similar manner as they are performed by a corresponding one of the plurality of components before the integration. According to embodiments, operations performed by the module, the program, or another component may be carried out sequentially, in parallel, repeatedly, or heuristically, or one or more of the operations may be executed in a different order or omitted, or one or more other operations may be added.

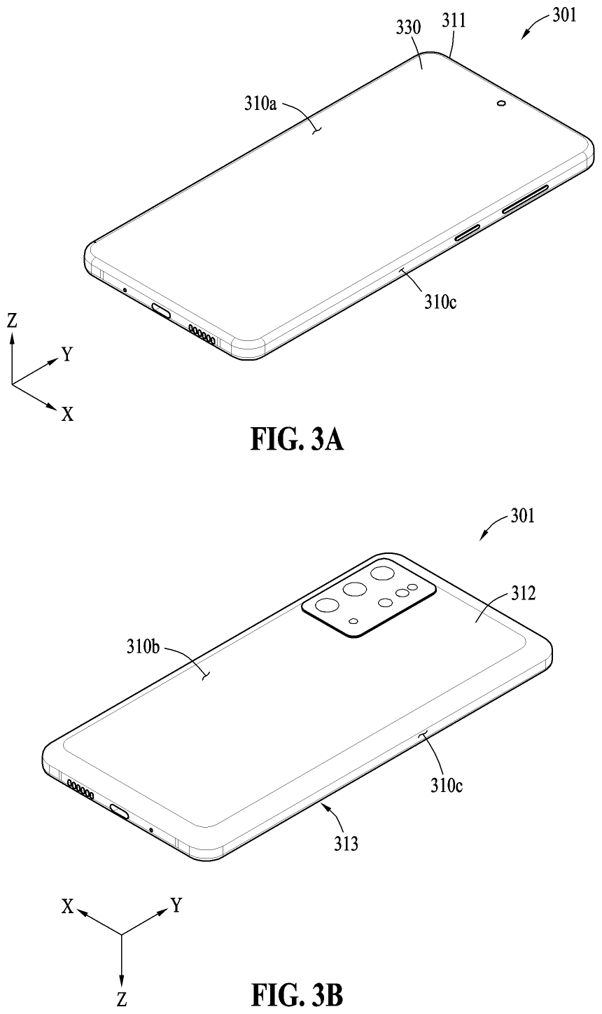

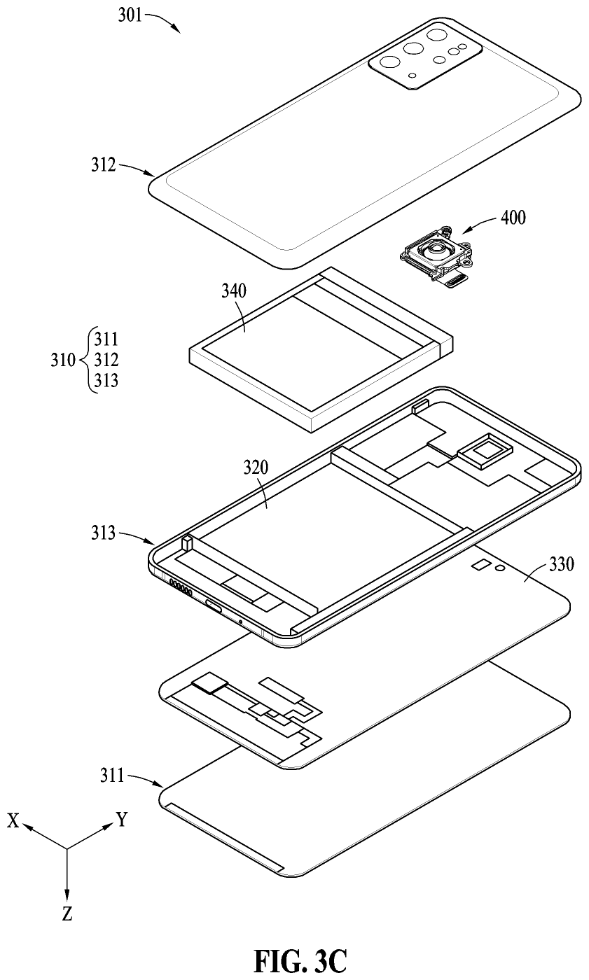

FIG. 3 is a front perspective view of an electronic device 301 according to various embodiments, FIG. 3B is a rear perspective view of an electronic device 301 according to various embodiments, and FIG. 3C is an exploded perspective view of an electronic device 301 according to various embodiments.

Referring to FIGS. 3A, 3B, and 3C, an electronic device 301 in an embodiment (e.g., the electronic device 101 of FIG. 1) may include a housing 310, a support member 320, a display 330, a main printed circuit board (PCB) 340, and a camera module 400.

In an embodiment, the housing 310 may form an exterior of the electronic device 301. The housing 310 may form a front surface 310a (e.g., a first surface), a rear surface 310b (e.g., a second surface), and a side surface 310c (e.g., a third surface) surrounding an inner space between the front surface 310a and the rear surface 310b. For example, the housing 310 may include a first plate 311 (e.g., a front plate), a second plate 312 (e.g., a rear plate), and a side member 313 (e.g., a side bezel structure).

In an embodiment, the front surface 310a may be formed by (or defined by) the first plate 311 of which at least a portion is substantially transparent. For example, the first plate 311 may include a polymer plate or a glass plate, including at least one coating layer. In an embodiment, the rear surface 310b may be formed of the second plate 312 which is substantially opaque. For example, the second plate 312 may be formed of coated or tinted glass, ceramic, polymer, metal (e.g., aluminum, stainless steel, or magnesium), or a combination thereof. The side surface 310C may be coupled to the first plate 311 and the second plate 312 and may be formed by the side member 313, including metal and/or polymer. In an embodiment, the second plate 312 and the side member 313 may be integrally and seamlessly formed as a unitary member. In an embodiment, the second plate 312 and the side member 313 may be formed of substantially the same material (e.g., aluminum).

In an embodiment, the side member 313 may surround at least a portion of the inner space defined between the front surface 310a and the rear surface 310b. The support member 320 may be disposed in the inner space of the housing 310. For example, the support member 320 may be connected to the side member 313 or may be formed integrally with the side member 313. The support member 320 may form an arrangement space for components of the electronic device 301. For example, the support member 320 may connect an edge of the first plate 311 to an edge of the second plate 312 and may enclose a space between the first plate 311 and the second plate 312. For example, the display 330 may be coupled to a surface (e.g., a surface in the +z direction) of the support member 320. However, this is an example, and the number and/or location of the support member 320 is not limited thereto.

In an embodiment, the electronic device 301 may include the display 330 (e.g., the display module 160 of FIG. 1). In an embodiment, the display 330 may be disposed on the front surface 310a. In an embodiment, the display 330 may be exposed (e.g., physically and/or visually) through at least a portion of the front plate 311. In an embodiment, the display 330 may have a shape (e.g., a planar shape) which is substantially the same as a shape of an outer edge of the first plate 311. In an embodiment, an outer edge of the display 330 may substantially coincide with the outer edge of the first plate 311.

In an embodiment, the main PCB 340 may be disposed in an inner space formed by the housing 310. The main PCB 340 may be supported by the support member 320 in the housing 310. For example, the main PCB 340 may be positioned in a rear direction (e.g., the −z direction) of the support member 320 and may be supported. However, this is an example, and the number and/or location of the main PCB 340 is not limited thereto. For example, in an embodiment, the main PCB 340 may be positioned in a front direction (e.g., the +z direction) of the support member 320 and may be supported. For example, in the main PCB 340, various circuits may be formed or electronic components may be disposed to drive the electronic device 301.

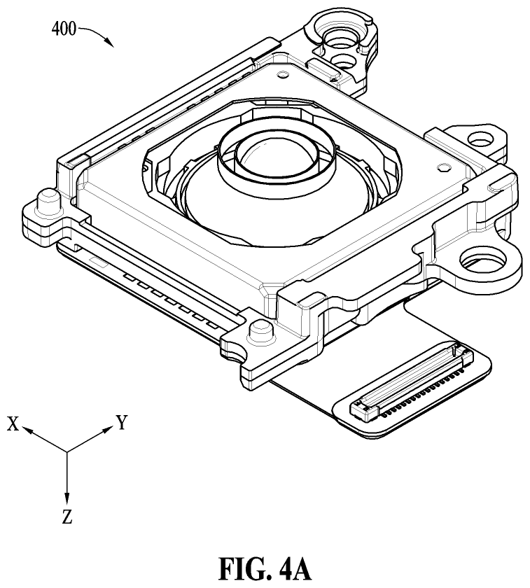

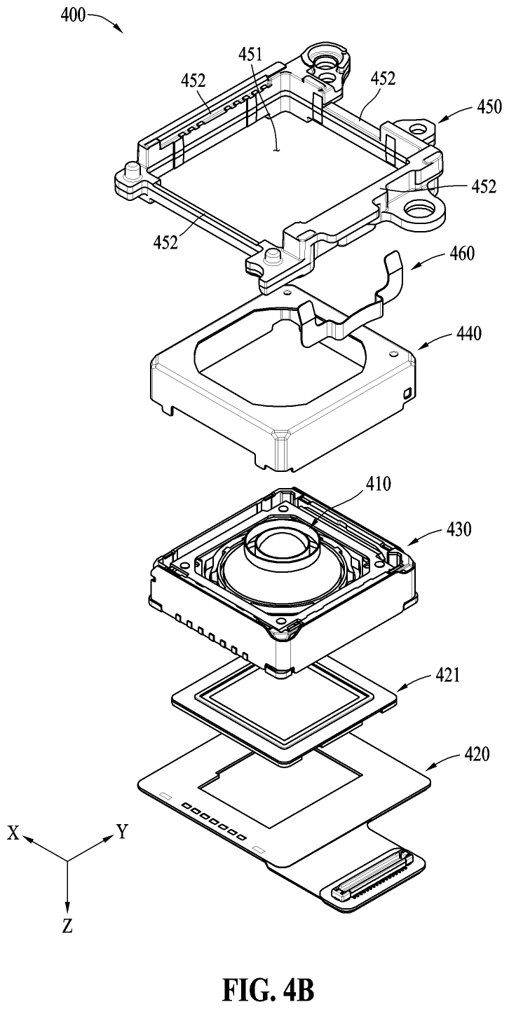

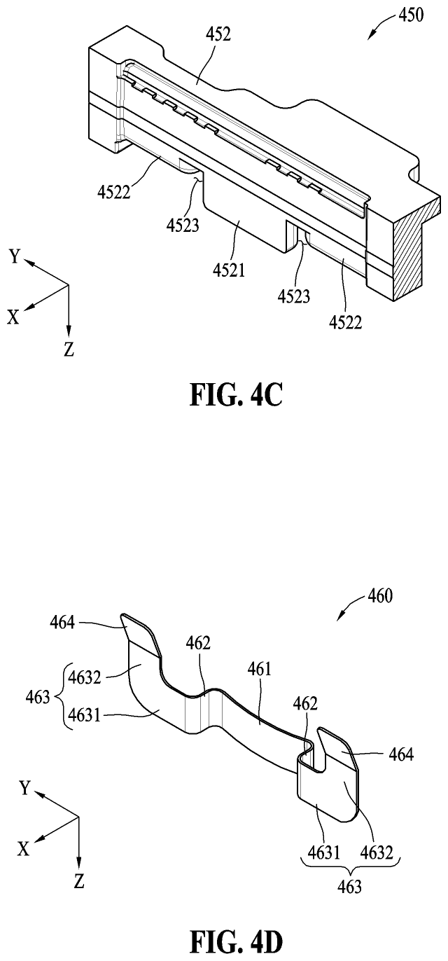

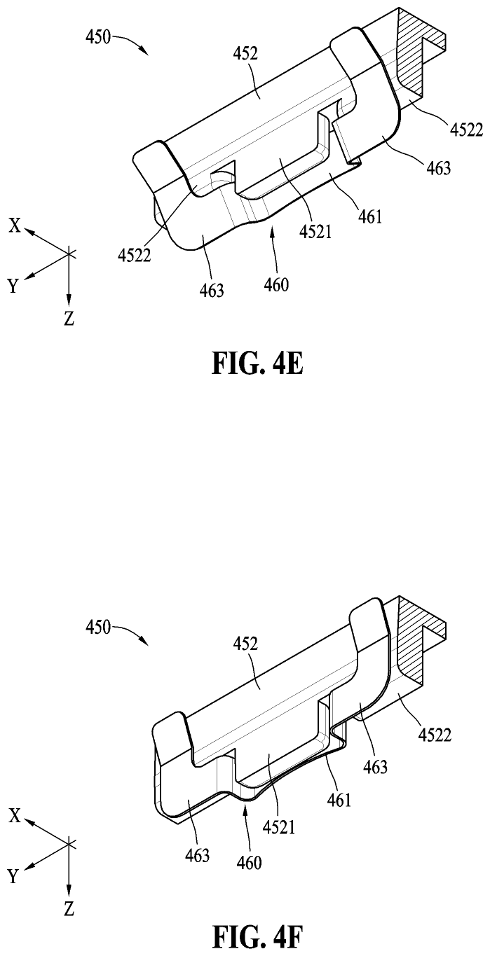

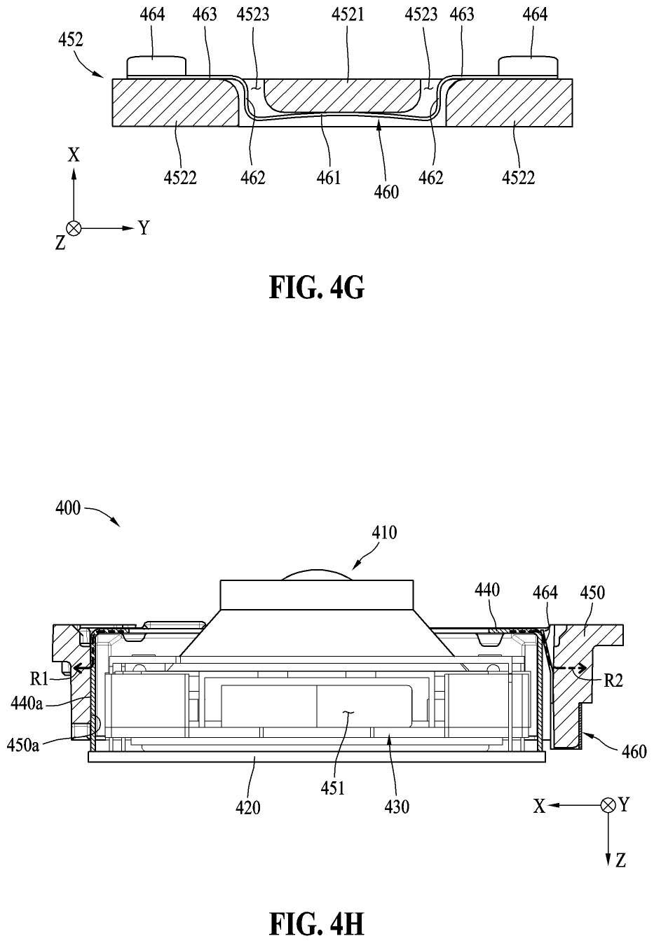

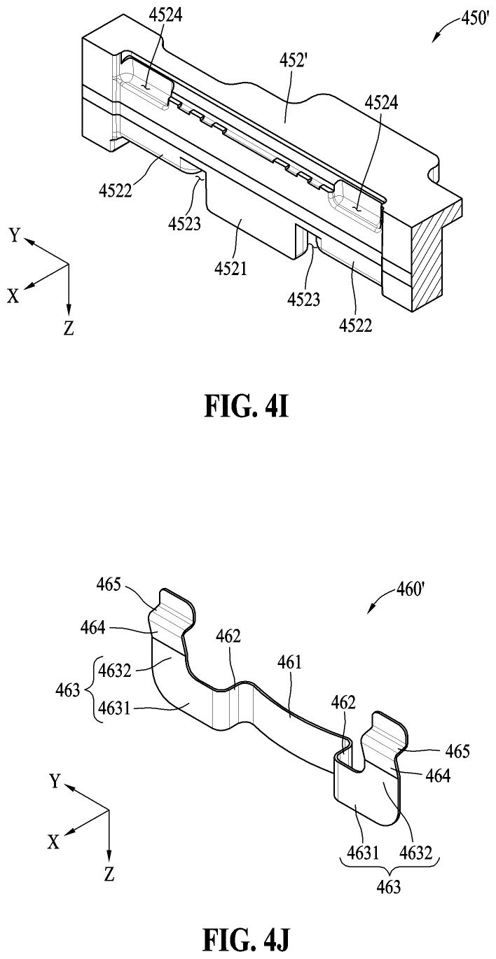

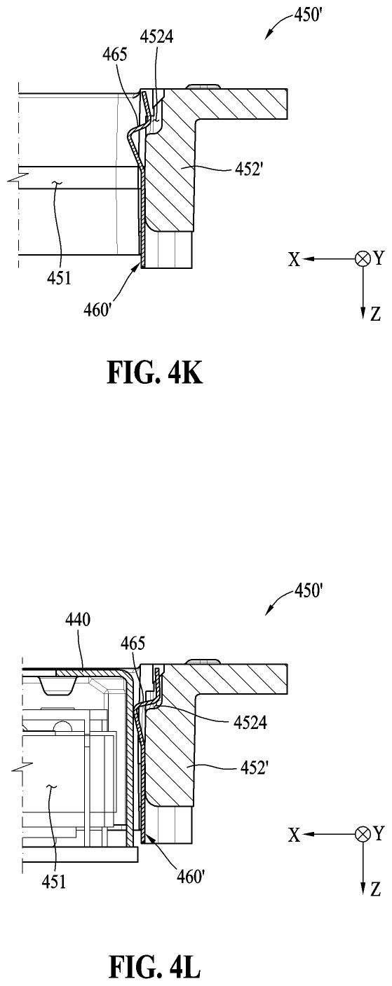

In an embodiment, the electronic device 301 may include the camera module 400 (e.g., the camera module 180 of FIG. 1). The camera module 400 may be fixedly connected to the support member 320 by a bracket (e.g., a bracket 450 of FIG. 4B) described below. The camera module 400 may be electrically connected to the main PCB 340. In an embodiment, the camera module 400 may be disposed to be visually exposed through (or at) the rear surface 310b of the housing 310, to outside the housing 310. Although FIG. 3C illustrates one camera module 400, this is an example for ease of description and illustration. The number and/or location of the camera module 400 is not limited thereto. For example, in an embodiment, a plurality of camera modules 400 may be provided. For example, in an embodiment, the camera module 400 may be disposed to be visually exposed through (or at) the front surface 310a of the housing 310, to outside the housing 310.

FIG. 4A is a perspective view of a camera module 400 according to an embodiment. FIG. 4B is an exploded perspective view of a camera module 400 according to an embodiment.

Referring to FIGS. 4A and 4B, in an embodiment, the camera module 400 (e.g., the camera module 180 of FIG. 1) may include a lens assembly 410 (e.g., the lens assembly 210 of FIG. 2), a PCB 420, an actuator 430, a shield can 440, a bracket 450, and an elastic structure 460.

In an embodiment, the lens assembly 410 may collect light reflected by an object which is a target of which an image is to be captured by a function of the electronic device 301. The lens assembly 410 may include one lens or a plurality of lenses. The camera module 400 as a functional component of the electronic device 301 may include one or a plurality of lens assemblies 410. The lens assembly 410 may be disposed in an inner space of the actuator 430 described below.

In an embodiment, the PCB 420 may include an image sensor 421 (e.g., the image sensor 230 of FIG. 2). The PCB 420 may process an image obtained by the image sensor 421. For example, the PCB 420 may be disposed in a lower direction (e.g., the +z direction) of the lens assembly 410. The PCB 420 may be electrically connected to a main PCB (e.g., the main PCB 340 of FIG. 3C) of an electronic device (e.g., the electronic device 301 of FIG. 3C).

In an embodiment, the actuator 430 may adjust a position (e.g., a physical position) of the lens assembly 410. For example, the actuator 430 may implement an autofocus function by moving the lens assembly 410 in (or along) an optical axis direction (e.g., the z direction). For example, the actuator 430 may implement an image stabilization function by moving the lens assembly 410 in a horizontal direction (e.g., the x and/or y direction). Such horizontal direction may be a planar direction along a plane defined by the x direction and the y direction which cross each other. The actuator 430 may include a voice coil motor using an electromagnetic force. For example, the actuator 430 may adjust the position of the lens assembly 410 by using a magnet and/or a coil. However, this is an example, and an operating direction and/or an operating method of the actuator 430 is not limited thereto.

In an embodiment, the shield can 440 may be positioned to cover at least a portion of the actuator 430. For example, the shield can 440 may cover the actuator 430 in an upper direction (e.g., the −z direction). For example, the shield can 440 may cover an edge portion of an upper portion of the actuator 430 to expose the lens assembly 410 to the outside of the shield can 440 while covering the side wall of the actuator 430. For example, the shield can 440 may be formed of or include a conductive material. As the shield can 440 is disposed to cover at least a portion of the actuator 430, the shield can 440 may shield the actuator 430 (e.g., electromagnetically shield).

In an embodiment, the bracket 450 may include (or define) an accommodation space 451 by sides or side walls of the bracket 450 which encloses the shield can 440. For example, the bracket 450 may include at least one side wall 452 extended to form a portion of the accommodation space 451 therein. For example, the bracket 450 may include four side walls 452 which together form the accommodation space 451. The shield can 440 may be inserted into and accommodated in the accommodation space 451 of the bracket 450. For example, the shield can 440 may be inserted into the accommodation space 451 of the bracket 450 in a direction (e.g., the −z direction) facing from a lower side to an upper side. While the shield can 440 is accommodated in the accommodation space 451, the bracket 450 may enclose the shield can 440 along the outer side of the shield can 440.

In an embodiment, the bracket 450 may fix the camera module 400 to the inside of an electronic device (e.g., the electronic device 301 of FIG. 3A). For example, the bracket 450 may fix the camera module 400 to a support member (e.g., the support member 320 of FIG. 3C). The bracket 450 may be formed of a conductive material. At least a portion of the bracket 450 may be electrically connected to the main PCB 340 of the electronic device 301. For example, the bracket 450 may be electrically connected to a ground layer of a main PCB (e.g., the main PCB 340 of FIG. 3C).

In an embodiment, the elastic structure 460 may be connected to or engaged with the bracket 450 such that at least a portion of the elastic structure 460 is disposed between the shield can 440 and the bracket 450. For example, the elastic structure 460 may be elastically engaged with one side wall 452 of the bracket 450. For example, the elastic structure 460 may be engaged with the side wall 452 in a direction (e.g., the −z direction) facing from the lower side to the upper side of the bracket 450. The elastic structure 460 may be formed of a material having elasticity and may autonomously generate an elastic force or a biasing force. At least a portion of the elastic structure 460 may be positioned in the accommodation space 451 and may generate an elastic force which presses the shield can 440 in one direction (e.g., the +x direction) in the accommodation space 451. The elastic structure 460 may be formed of a material which is conductive and non-magnetic. As the elastic structure 460 is positioned between the shield can 440 and the bracket 450, the elastic structure 460 may electrically connect the shield can 440 to the bracket 450. As the elastic structure 460 is formed of a material which is non-magnetic, interference with a driving signal of the actuator 430 may be prevented.

FIG. 4C is a partial perspective view of a side wall 452 of a bracket 450 according to an embodiment. FIG. 4D is a perspective view of an elastic structure 460 according to an embodiment. FIG. 4E is a perspective view of a process of engaging an elastic structure 460 with a bracket 460 in an embodiment. FIG. 4F is a perspective view of a state in which an elastic structure 460 is engaged with a bracket 450 in an embodiment. FIG. 4G is a bottom view of a state in which an elastic structure is engaged with a bracket in an embodiment.

Referring to FIGS. 4C to 4G, a head 4521 as a protrusion or a tab, a shoulder 4522, and a groove 4523 may be formed on the side wall 452 of a bracket (e.g., the bracket 450 of FIG. 4B) in an embodiment. Hereinafter, for ease of description, based on the side wall 452, a direction facing an accommodation space (e.g., the accommodation space 451 of FIG. 4B) may be referred to as an inward direction (e.g., the +x direction) and a direction facing the outside may be referred to as an outward direction (e.g., the −x direction).

In an embodiment, the head 4521 may relatively protrude in a lower direction (e.g., the +z direction) in a lower portion (e.g., a portion in the +z direction) of the side wall 452. For example, the head 4521 may be substantially formed near the center of the side wall 452. A pair of shoulders 4522 may be formed extended from opposite sides of the head 4521 and extended in opposing directions (e.g., sides in +y and −y directions) of the head 4521. The pair of shoulders 4522 may be spaced apart and may be respectively positioned at both sides (e.g., the sides in +y and −y directions) of the head 4521. A pair of grooves 4523 may be formed between the head 4521 and the pair of shoulders 4522. The inner edges of the pair of shoulders 4522 may be rounded. However, this is an example, and the shapes and/or locations of the head 4521, the shoulder 4522, and/or the groove 4523 are not limited thereto.

Referring to FIGS. 4C to 4G, in an embodiment, the elastic structure 460 may include a support 461, a connector 462, an arm portion 463, and an inclined portion 464.

In an embodiment, the support 461 may be a portion in contact with an outer side surface (e.g., the surface in the −x direction) of the head 4521 which is opposite to the inner side surface facing the accommodation space 451. For example, as shown in FIG. 4G, the support 461 may be formed as a curved surface such that a central portion of the support 461 is in contact with the outer side surface (e.g., the surface in the −x direction) of the head 4521. The support 461 formed as a curved surface may be elastically deformable. The elastic structure 460 may be deformable at various curved surfaces or at locations where a direction of curvature changes (e.g., an inflection point).

In an embodiment, the pair of connectors 462 may be bent and may extend toward an inner side (e.g., the +x direction) from both sides (e.g., sides in the +y and −y directions) of the support 461, respectively. While the elastic structure 460 is engaged with the side wall 452 of the bracket 450, the pair of connectors 462 may be inserted into and positioned in the respective grooves 4523. The pair of connectors 462 may face (or oppose) each other along the y direction. The support 461, the connector 462 and the arm portion 463 may together form a groove of the elastic structure 460 which is open along the z direction and into which the head 4521 may extend.

In an embodiment, the pair of arm portions 463 may be bent and may extend from ends (e.g., ends in the +x direction) of the respective connectors 462 in the +y and −y directions, respectively. At least a portion of the pair of arm portions 463 may be in contact with the inner side surface (e.g., the surface in the +x direction) of the shoulder 4522.

In an embodiment, each arm portion 463 may include a first arm portion 4631 and a second arm portion 4632. The first arm portion 4631 may be a portion which is bent and extends in the +y direction or the −y direction from the end (e.g., the end in the +x direction) of the respective connector 462. At least a portion of the first arm portion 4631 may be in contact with the inner side surface (e.g., the surface in the +x direction) of the shoulder 4522. The second arm portion 4632 may be a portion which is bent and extends in the upper direction (e.g., the −z direction) from the end (e.g., the end in the +y direction or the −y direction) of the first arm portion 4631. At least a portion of the second arm portion 4632 may be in contact with the inner side surface (e.g., the surface in the +x direction) of the side wall 452. For example, the arm portion 463 may be substantially formed in an “L” shape. However, this is an example, and the shape of the arm portion 463 is not limited thereto.

In an embodiment, a pair of inclined portions 464 may be inclinedly bent toward the inner side (e.g., the +x direction) from the end (e.g., the end in the −z direction) of the respective arm portions 463. For example, the pair of inclined portions 464 may be inclinedly bent toward the inner side (e.g., the +x direction) from the end (e.g., the end in the −z direction) of the second arm portion 4632. For example, while the elastic structure 460 is engaged with the side wall 452 of the bracket 450, an angle between the inclined portion 464 and the inner side surface (e.g., the surface in the +x direction) of the side wall 452 may form an acute angle.

In an embodiment, as shown in FIG. 4E, the elastic structure 460 may be engaged with the bracket 450 as the elastic structure 460 rotates from the outside (e.g., the −x direction) to the inside (e.g., the +x direction) in the lower portion (e.g., a portion in the +z direction) of the side wall 452. For example, while the support 461 is in contact with the outer side surface (e.g., the −x direction) of the head 4521, the elastic structure 460 may be engaged with the side wall 452 as the elastic structure 460 rotates from the outside (e.g., the −x direction) toward the inside (e.g., the +x direction). During this process, the arm portion 463 of the elastic structure 460 may ride over the shoulder 4522 as the arm portion 463 continuously contacts a round edge of the shoulder 4522. The elastic structure 460 may be rotated about a rotation axis extended along the y direction.

As shown in FIGS. 4F and 4G, when the elastic structure 460 is completely engaged with the side wall 452, the support 461 may be in contact with the outer side surface (e.g., the surface in the −x direction) of the bracket 450 at the head 4521 and the pair of arm portions 463 may be in contact with the inner side surface (e.g., the surface in the +x direction) of the bracket 450 at the side wall 452 and at the shoulder 4522. According to the state described above, the elastic structure 460 may be elastically engaged and coupled to the side wall 452 solely by an elastic force of the elastic structure 460.

FIG. 4H is a cross-sectional side view of a camera module 400 according to an embodiment.

Referring to FIG. 4H, at least a portion of the elastic structure 460 may be positioned between the shield can 440 and the bracket 450. For example, the inclined portion 464 of the elastic structure 460 may be positioned between the shield can 440 and the bracket 450. At least a portion (e.g., the inclined portion 464) of the elastic structure 460 may generate an elastic force which presses or biases the shield can 440 in one direction (e.g., the +x direction) in the accommodation space 451. The elastic structure 460 may be disposed at a first side of the accommodation space 451, such as shown by the right side in FIG. 4H. For example, the shield can 440 may be pressed in the +x direction in the accommodation space 451 by the elastic force of the elastic structure 460.

According to the elastic force described above, a state in which an outer side surface 440a of the shield can 440 is in contact with an inner side surface 450a of the bracket 450 at a second side of the accommodation space 451 which is opposite to the first side may be maintained. As being in contact, elements may be in physical contact with each other such as to form an interface (e.g., a physical interface) therebetween. Accordingly, a first ground path R1 (e.g., a first electrical ground path R1) may be formed by the contact (e.g., surface contact or planar contact) between the outer side surface 440a of the shield can 440 and the inner side surface 450a of the bracket 450.

In an embodiment, as the elastic structure 460 is positioned between the shield can 440 and the bracket 450 at the first side of the accommodation space 451, the elastic structure 460 may electrically connect the shield can 440 to the bracket 450. For example, a second ground path R2 leading from the shield can 440, to the elastic structure 460, and finally to the bracket 450 may be formed by mutual and respective contact of the shield can 440, the elastic structure 460, and the bracket 450 relative to each other.

In an embodiment, the shield can 440 may be maintained in a ground state with the bracket 450 by the first ground path R1 and the second ground path R2. Accordingly, electromagnetic compatibility performance by the shield can 440 which shields the actuator 430 may be stably secured. In addition, since the first ground path R1 and/or the second ground path R2 may be stably implemented by coupling the elastic structure 460 to the bracket 450, separate equipment may not be required, and an increase in manufacturing process time may be minimized.

In an embodiment, as the shield can 440 is pressed or biased in one direction (e.g., the +x direction) in the accommodation space 451 by the elastic force of the elastic structure 460, a position of the shield can 440 may be aligned in the accommodation space 451. Accordingly, the shield can 440 may be aligned in a designated position in the accommodation space 451.

In an embodiment, a direction in which the elastic structure 460 is engaged with the bracket 450 may be the same as a direction in which the shield can 440 is inserted into the accommodation space 451 of the bracket 450. For example, after the elastic structure 460 is engaged with the bracket 450 in the −z direction (e.g., from the front side to the rear side of the electronic device 301), the shield can 440 may be inserted into the accommodation space 451 in the same −z direction to define an insertion direction or a coupling direction. According to the structure described above, since the elastic structure 460 is elastically engaged between the shield can 440 and the bracket 450 and the shield can 440 substantially supports the elastic structure 460 from the lower side, the elastic structure 460 may be prevented from being removed from the bracket 450. In addition, since the PCB 420 is positioned in the lower direction (e.g., the +z direction) of the elastic structure 460, the elastic structure 460 may be prevented from being removed from the bracket 450 in the lower direction (e.g., the +z direction).

In addition, in an embodiment, an adhesive (not shown) may be applied between the shield can 440 and the bracket 450. For example, an adhesive may be applied to an upper end (e.g., the end in the −z direction) between the shield can 440 and the bracket 450. For example, the adhesive may be an ultraviolet (UV) epoxy adhesive. By the adhesive described above, a fixing force between the shield can 440 and the bracket 450 may be improved and furthermore, the elastic structure 460 may be prevented from being removed from the bracket 450.

FIG. 4I is a partial perspective view of a side wall 452′ of a bracket 450′ according to an embodiment. FIG. 4J is a perspective view of an elastic structure 460′ according to an embodiment. FIG. 4K is a cross-sectional side view of a state in which an elastic structure 460′ is engaged with a bracket 450′ in an embodiment. FIG. 4L is a partial cross-sectional side view of a state in which an elastic structure is engaged with a bracket and a shield can is inserted into an accommodation space in an embodiment.

Referring to FIGS. 4I to 4L, the head 4521, the shoulder 4522, the groove 4523 as a first groove, and a stepped groove 4524 as a second groove may be formed in a side wall 452′ of a bracket 450′ in an embodiment. The first groove may be open in the +z direction which the second groove is open in the +x direction and facing the accommodation space 451. Since the head 4521, the shoulder 4522, and the groove 4523 of FIG. 4I are the same as the head 4521, the shoulder 4522, and the groove 4523 described with reference to FIG. 4C, a detailed description thereof is omitted.

In an embodiment, a pair of stepped grooves 4524 may be recessed from an inner side surface (e.g., a surface in the +x direction) of an upper portion (e.g., a portion in the −z direction) of the side wall 452′. For example, the pair of stepped grooves 4524 may be recessed from the upper side (e.g., the side in the +z direction) toward the lower side (e.g., the side in the −z direction). That is, the second groove may be open in the +x and in the −z directions, at an inner surface of the side wall 452′. The pair of stepped grooves 4524 may be spaced apart from each other along a length of the bracket 450′. For example, the pair of stepped grooves 4524 may be formed at a position substantially corresponding to the pair of shoulders 4522 in the y direction. Here, the shoulder 4522 may define the second groove, without being limited thereto.

In an embodiment, an elastic structure 460′ may include the support 461, the connector 462, the arm portion 463, the inclined portion 464, and a stepped portion 465. The support 461, the connector 462, the arm portion 463, and the inclined portion 464 of FIG. 4J are the same as the support 461, the connector 462, the arm portion 463, and the inclined portion 464 described with reference to FIG. 4D, a detailed description thereof is omitted.

In an embodiment, a pair of stepped portions 465 may be stepped and may extend outwardly (e.g., the −x direction) from ends (e.g., ends in the −z direction) of the respective inclined portions 464. For example, after the stepped portion 465 is bent in the −x direction from the end (e.g., the end in the −z direction) of the inclined portion 464, the stepped portion 465 may be bent and may extend in the −z direction. Here, an end portion of the arm portion 463 may be defined by the inclined portion 464 together with the stepped portion 465. Relative to the z direction along which the arm portion 463 extends, the end portion extends in both of the +x and the −x directions, at the the inclined portion 464 and the stepped portion 465, respectively.

In an embodiment, as shown in FIG. 4K, in a state in which the elastic structure 460′ is engaged with the bracket 450′ but unengaged with the shield can 440, the stepped portion 465 of the elastic structure 460′ may be spaced apart from an inner surface of the bracket 450′ at the stepped groove 4524. As shown in FIG. 4L, when the shield can 440 is inserted into the accommodation space 451 of the bracket 450′, the elastic structure 460′ may be elastically deformed by contact of the shield can 440 with the elastic structure 460′ at the inclined portion 464. For example, as the inclined portion 464 is elastically deformed in an outward direction (e.g., the −x direction) by the contact between the shield can 440 and the inclined portion 464, the stepped portion 465 may be substantially seated on the stepped groove 4524. According to the structure described above, while the shield can 440 is inserted into the accommodation space 451 of the bracket 450′, the stepped portion 465 may be seated on the stepped groove 4524, and thereby, the elastic structure 460′ may be prevented from being removed from the bracket 450′.

Similar to that discussed above and shown in FIGS. 4F and 4G, when the elastic structure 460′ is completely engaged with the side wall 452′, the support 461 may be in contact with the outer side surface (e.g., the surface in the −x direction) of the bracket 450′ at the head 4521 and the pair of arm portions 463 may be in contact with the inner side surface (e.g., the surface in the +x direction) of the bracket 450′ at the side wall 452′ and at the shoulder 4522.

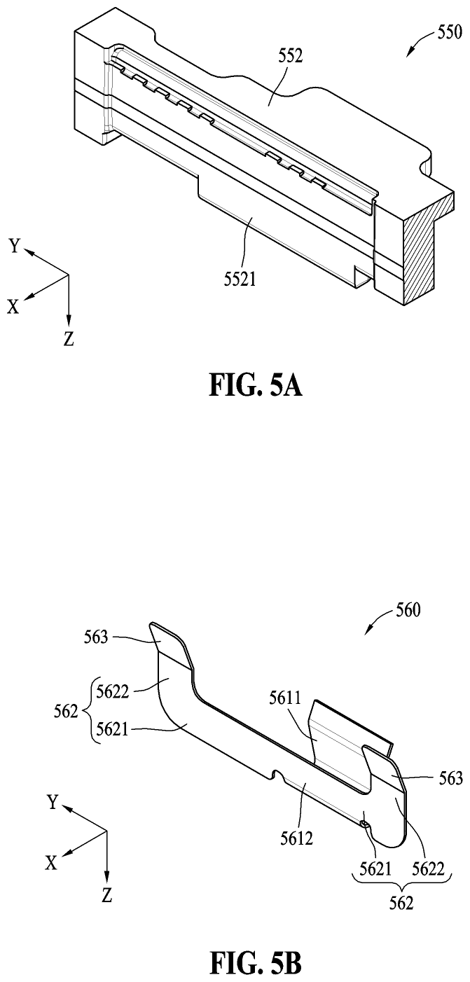

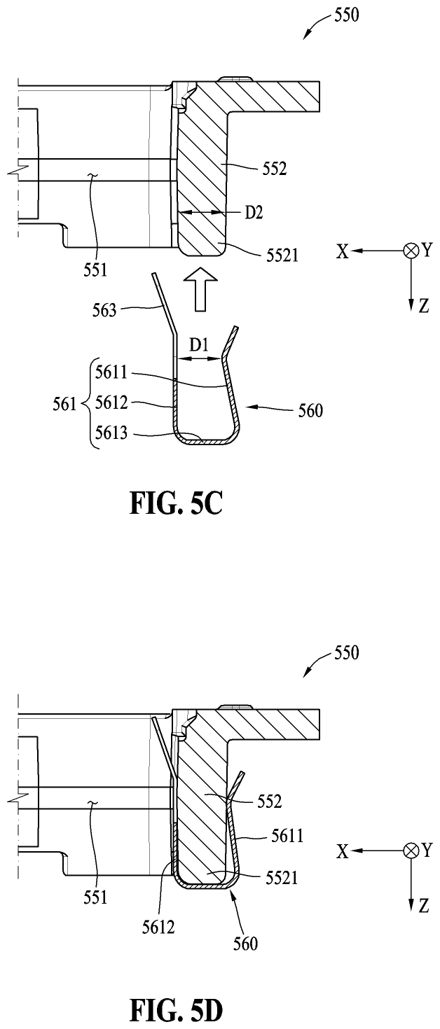

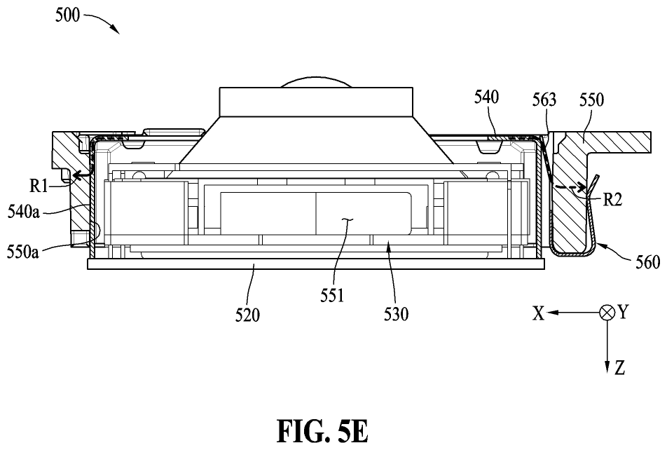

FIG. 5A is a partial perspective view of a side wall 550 of a bracket according to an embodiment. FIG. 5B is a perspective view of an elastic structure 560 according to an embodiment. FIG. 5C is a cross-sectional side view of a process of engaging an elastic structure 560 with a bracket 550 in an embodiment. FIG. 5D is a cross-sectional side view of a state in which an elastic structure 560 is engaged with a bracket 550 in an embodiment.

Referring to FIGS. 5A to 5D, a head 5521 may be formed in a side wall 552 of a bracket 550 in an embodiment (e.g., the bracket 450 of FIG. 4B). The head 5521 may relatively protrude from a lower portion (e.g., a portion in the +z direction) of the side wall 552 in the lower direction (e.g., +z direction). For example, the head 5521 may be substantially formed near the center of the side wall 552. However, this is an example and the head 5521 may be a portion of the lower portion (e.g., the portion in the +z direction) of the side wall 552.

Referring to FIGS. 5A to 5D, in an embodiment, an elastic structure 560 may include a clip portion 561, an arm portion 562, and an inclined portion 563.

In an embodiment, the clip portion 561 may be elastically engaged with the side wall 552. For example, the clip portion 561 may be elastically engaged with the bracket 550 at the head 5521 of the side wall 552. The clip portion 561 may include a first support 5611, a second support 5612, and a connector 5613. The first support 5611 may be in contact with an outer side surface (e.g., a surface in the −x direction) of the head 5521. At least a portion of the first support 5612 may be inclinedly formed toward the inner side (e.g., the +x direction). An end (e.g., an end in the −z direction) of the first support 5612 may be inclinedly formed toward the outside (e.g., the −x direction). The second support 5612 may be in contact with an inner side surface (e.g., a surface in the +x direction) of the head 5521. The connector 5613 may connect the first support 5611 to the second support 5612.

Referring to FIG. 5C, before the clip portion 561 is engaged with the side wall 552, a portion of a distance D1 in a width (e.g., a width in the x direction or the biasing direction) direction between an inner surface of the first support 5611 and an inner surface of the second support 5612 which face each other may be less than a width D2 (e.g., a width in the x direction) of the head 5521.

According to the structure described above, during a process of engaging the clip portion 561 with the side wall 552, the first support 5611 and the second support 5612 may elastically spread in opposite directions from each other. As shown in FIG. 5D, when the clip portion 561 is completely engaged with the side wall 552, an elastic force may be generated between the first support 5611 and the second support 5612 in respective directions towards the facing support and thereby, a state in which the elastic structure 560 is engaged with the side wall 552 may be maintained. Here, the elastic member 560 may be coupled to the head 5521 solely by the elastic force between the first support 5611 and the second support 5612 which are on opposite sides of the head 5521.

In an embodiment, a pair of arm portions 562 may extend to each of opposing sides from opposing ends (e.g., ends in the +y and −y directions) of the clip portion 561, respectively. At least a portion of the pair of arm portions 562 may be in contact with the inner side surface (e.g., the surface in the +x direction) of the side wall 552.

In an embodiment, each arm portion 562 may include a first arm portion 5621 and a second arm portion 5622. The first arm portion 5621 may be a portion which extends from both ends (e.g., ends in the +y and −y directions) of the clip portion 561 to both sides. The second arm portion 5622 may be a portion which is bent and extends in the upper direction (e.g., the −z direction) from an end (e.g., an end in the +y direction or the −y direction) of the first arm portion 5621. For example, the arm portion 562 may be substantially formed in an “L” shape within the y-z plane. However, this is an example, and the shape of the arm portion 562 is not limited thereto.

In an embodiment, a pair of inclined portions 563 may be inclinedly bent toward the inner side (e.g., the +x direction) from the ends (e.g., the ends in the −z direction) of the arm portions 562, respectively. For example, the pair of inclined portions 563 may be inclinedly bent toward the inner side (e.g., the +x direction) from the end (e.g., the end in the −z direction) of the second arm portion 5622. For example, while the elastic structure 560 is engaged with the side wall 552 of the bracket 550, an angle between the inclined portion 563 and the inner side surface (e.g., the surface in the +x direction) of the side wall 552 may form an acute angle.

FIG. 5E is a cross-sectional side view of a camera module 500 which is assembled according to an embodiment.

Referring to FIG. 5E, at least a portion of the elastic structure 560 may be positioned between the shield can 540 and the bracket 550. For example, the inclined portion 563 of the elastic structure 560 may be positioned between the shield can 540 and the bracket 550. At least a portion (e.g., the inclined portion 563) of the elastic structure 560 may generate an elastic force which presses the shield can 540 in one direction (e.g., the +x direction) in an accommodation space 551. For example, the shield can 540 may be pressed in the +x direction in the accommodation space 551 by the elastic force of the elastic structure 560. According to the elastic force described above, a state in which an outer side surface 540a of the shield can 540 is in contact with an inner side surface 550a of the bracket 550 may be maintained. Accordingly, a first ground path R1 may be formed by the contact (e.g., surface contact) between the outer side surface 540a of the shield can 540 and the inner side surface 550a of the bracket 550.

In an embodiment, as the elastic structure 560 is positioned between the shield can 540 and the bracket 550, the elastic structure 560 may electrically connect the shield can 540 to the bracket 550. For example, a second ground path R2 from the shield can 540, through the elastic structure 560, and to the bracket 550 may be formed by mutual contact with the shield can 540, the elastic structure 560, and the bracket 550.

In an embodiment, the shield can 540 may be maintained in a ground state with the bracket 550 by the first ground path R1 and the second ground path R2. Accordingly, electromagnetic compatibility performance by the shield can 540 which shields the actuator 530 may be stably secured. In addition, since the first ground path R1 and/or the second ground path R2 may be stably implemented by coupling the elastic structure 560 to the bracket 550, separate equipment may not be required and an increase in manufacturing process time may be minimized.

In an embodiment, as the shield can 540 is pressed in one direction (e.g., the +x direction) in the accommodation space 551 by the elastic force of the elastic structure 560, a position of the shield can 540 may be aligned in the accommodation space 551. Accordingly, the shield can 540 may be aligned in a designated position in the accommodation space 551.

In an embodiment, a direction in which the elastic structure 560 is engaged with the bracket 550 may be the same as an insertion direction in which the shield can 540 is inserted into the accommodation space 551 of the bracket 550. For example, after the elastic structure 560 is engaged with the bracket 550 in the −z direction (e.g., the insertion direction indicated by the arrow in FIG. 5C), the shield can 540 may be inserted into the accommodation space 551 in the same −z direction. According to the structure described above, since the elastic structure 560 is elastically engaged between the shield can 540 and the bracket 550 and the shield can 540 substantially supports the elastic structure 560 from the lower side, the elastic structure 560 may be prevented from being removed from the bracket 550. In addition, since a PCB 520 is positioned in the lower direction (e.g., the +z direction) of the elastic structure 560, the elastic structure 560 may be prevented from being removed from the bracket 550 in the lower direction (e.g., the +z direction).

In addition, in an embodiment, an adhesive (not shown) may be applied between the shield can 540 and the bracket 550. For example, an adhesive may be applied to an upper end (e.g., the end in the −z direction) between the shield can 540 and the bracket 550. For example, the adhesive may be a UV epoxy adhesive. By the adhesive described above, a fixing force between the shield can 540 and the bracket 550 may be improved and furthermore, the elastic structure 560 may be prevented from being removed from the bracket 550.

In various embodiments, the electronic device 301 may include the housing 310 configured to form the exterior of the electronic device 301, the support member 320 disposed in an inner space of the housing 310, and the camera module 400 fixedly connected to the support member 320, where the camera module 400 may include the lens assembly 410, the PCB 420 including the image sensor 421, the actuator 430 configured to adjust a position of the lens assembly 410, the shield can 440 positioned to cover at least a portion of the actuator 430, the bracket 450 including the accommodation space 451 enclosing the shield can 440 and configured to fix the camera module 400 to the support member 320, and the elastic structure 460 of which at least a portion is connected to the bracket 450 to be positioned between the shield can 440 and the bracket 450 and which is configured to generate an elastic force which presses the shield can 440 in one direction in the accommodation space 451, and the shield can 440 may be electrically connected to the bracket 450 by the elastic structure 460.

Here, the electronic device 301 includes a camera module fixed to the support member, where the camera module includes a bracket fixed to the support member, the bracket including an accommodation space defined therein, and within the accommodation space a lens and an actuator which adjusts a position of the lens, a shield can which covers the actuator, and an elastic structure which electrically connects the shield can to the bracket. The elastic structure includes an elastic portion which is between the shield can and the bracket and provides an elastic force to the shield can, where the shield can and the bracket are electrically connected to each other at the elastic portion of the elastic structure.

In various embodiments, a state in which the outer side surface 440a of the shield can 440 is in contact with the inner side surface 450a of the bracket 450 may be maintained by the elastic force of the elastic structure 460. That is, the elastic structure electrically connects the shield can to the bracket at a first side of the accommodation space, the elastic structure provides the elastic force to the shield can in a direction toward a second side of the accommodation space which is different from the first side, and the elastic force of the elastic structure maintains an outer side surface of the shield can in contact with an inner side surface of the bracket at the second side of the accommodation space.

In various embodiments, the bracket 450 may include at least one side wall forming the accommodation space 451 and the elastic structure 460 may be engaged with the side wall 452 of the bracket 450.

In various embodiments, the direction in which the elastic structure 460 is engaged with the bracket 450 may be the same as the direction in which the shield can 440 is inserted into the accommodation space 451 of the bracket 450. That is, the elastic portion is between the shield can and the bracket at an upper side of the side wall, insertion of the elastic structure into the accommodation space in an insertion direction from a lower side of the side wall to the upper side thereof engages the elastic structure with the side wall of the bracket, and insertion of the shield can into the accommodation space in the insertion direction electrically connects the shield can to the bracket at the elastic portion of the elastic structure.

In various embodiments, the bracket 450 may further include the head 4521 formed in the side wall 452 and the pair of shoulders 4522 respectively formed on both sides of the head 4521. That is, the bracket may further include a head which protrudes from a lower side of the side wall which is opposite to the upper side, the elastic structure being engaged with the side wall at the head, and a pair of shoulders respectively extended from opposing ends of the head, the elastic structure which is engaged with the side wall at the head extended along the pair of shoulders.

In various embodiments, the elastic structure 460 may include the support 461 contacting the outer side surface of the head 4521, the pair of connectors 462 respectively bent and extending from both sides of the support 461 toward the inside, and the pair of arm portions 463 bent and extending from ends of the connectors 462 such that at least a portion of the pair of arm portions 463 is in contact with the inner side surface of the shoulder 4522. That is, the elastic structure may include a pair of connectors respectively bent from opposing ends of the support and in a direction toward the accommodation space, a pair of arm portions which are bent from ends of the pair of connectors, respectively, and the pair of arm portions in contact with an inner side surface of a respective shoulder.

In various embodiments, the elastic structure 460 may further include the pair of inclined portions 464 inclinedly bent inwardly from ends of the arm portions 463, respectively, and the pair of inclined portions 464 may be positioned between the shield can 440 and the bracket 450 and may press the shield can 440 in one direction in the accommodation space 451. That is, the elastic structure may further include a pair of inclined portions inclined from ends of the pair of arm portions, respectively, in the direction toward the accommodation space, and the pair of inclined portions between the shield can and the bracket and providing the elastic force to the shield can in the direction toward the accommodation space.

In various embodiments, the support 461 may be formed as a curved surface such that a central portion of the support 461 (e.g., a curved central portion) is in contact with the outer side surface of the head 4521.

In various embodiments, the elastic structure 460′ may further include the pair of stepped portions 465 stepped and extending from ends of the inclined portions 464 outwardly, the bracket 450′ may further include the pair of stepped grooves 4524 formed on an inner side of the side wall 452′, and while the elastic structure 460′ is engaged with the bracket 450′ and the shield can 440 is inserted into the accommodation space 451, the stepped portions 465 may be seated on the stepped grooves 4524, respectively. That is, the elastic structure may further include a pair of stepped portions stepped from ends of the pair of inclined portions, respectively, in a direction away from the accommodation space, the bracket may further include a pair of stepped grooves recessed in the side wall at the upper side of the side wall, the pair of stepped grooves being open to the accommodation space, and the elastic structure which electrically connects the shield can to the bracket includes the elastic portion providing the elastic force to the shield can in the direction toward the accommodation space together with the pair of stepped portions respectively engaged with the pair of stepped grooves of the bracket.

In various embodiments, the elastic structure 560 may include the clip portion 561 engaged with the side wall 552, and the pair of arm portions 562 extending from an end of the clip portion 561 to both sides such that at least a portion of the pair of arm portions 562 is in contact with an inner side surface of the side wall 552. That is, the elastic structure may further include a clip portion engaged with an outer side surface of the side wall, and a pair of arm portions extending from the clip portion, the pair of arm portions extending along an inner side surface of the side wall which is opposite to the outer side surface and contacting the inner side surface of the side wall.

In various embodiments, the elastic structure 560 may further include the inclined portion 563 inclinedly bent inwardly from an end of each of the arm portions 562, and the inclined portion 563 may be positioned between the shield can 540 and the bracket 550 and may press the shield can 540 in one direction in the accommodation space 551. That is, the elastic structure may further include an inclined portion inclined from an end of each of the arm portions, respectively, in a direction toward the accommodation space, and the inclined portion between the shield can and the bracket and providing the elastic force to the shield can in the direction toward the accommodation space.

In various embodiments, the clip portion 561 may include the first support 5611 in contact with the outer side surface of the side wall 552, the second support 5612 in contact with the inner side surface of the side wall 552, and the connector 5613 configured to connect the first support 5611 to the second support 5612, where, before the clip portion 561 is engaged with the side wall 552, at least a portion of a distance in a width direction between the first support 5611 and the second support 5612 may be less than the width of the side wall 552.

Here, the elastic portion of the elastic structure is between the shield can and the bracket and provides the elastic force to the shield can in a first direction. The clip portion may include a first support in contact with the outer side surface of the side wall, a second support in contact with the inner side surface of the side wall, and a connector which connects the first support to the second support. The clip portion which is unengaged with the side wall includes the first support and the second support spaced apart from each other in the first direction by a distance which is less than a width of the side wall in the first direction.

In various embodiments, the elastic structure 460 may be formed of a material which is conductive and non-magnetic.

Here, an electronic device includes a non-magnetic elastic structure which electrically connects the shield can to the bracket, the non-magnetic elastic structure including an elastic portion which is between the shield can and the bracket in a first direction, contacts the side wall and provides an elastic force to the shield can in the first direction to fix the shield can to the bracket.

In an embodiment, the stepped portion may be extended inclined from an end of the elastic portion in a direction opposite to the first direction, the bracket may further include a groove recessed in the side wall and open to the accommodation space, and the non-magnetic elastic structure may include the elastic portion which is in contact with both the inner side surface of the side wall and the outer side surface of the shield can together with the stepped portion being in the groove of the bracket.

In an embodiment, the side wall includes an inner side surface facing the accommodation space, an outer side surface which is opposite to the inner side surface, and a lower end which connects the outer side surface to the inner side surface. The non-magnetic elastic structure may further include a clip portion extended from the elastic portion, the clip portion extending from the inner side surface of the side wall to the outer side surface of the side wall via the lower surface of the side wall.

In an embodiment, the camera module may include a bracket which is fixed to the housing and includes an accommodation space defined by a side wall which surrounds the accommodation space, the side wall including an inner side surface facing the accommodation space and an outer side surface which is opposite to the inner side surface, and grooves defined therein which are spaced apart from each other and open at both the inner side surface and the outer side surface of the side wall (refer to grooves 4523 in FIG. 4G, for example). The camera module may include within the accommodation space which is surrounded by the side wall are a lens assembly including a lens, an actuator which adjusts a position of the lens, and a shield can which covers the actuator and is fixed to the bracket. a non-magnetic elastic structure which is fixed to the bracket and electrically connects the shield can to the bracket, the non-magnetic elastic structure including an elastic portion which is between the shield can and the bracket in a first direction, contacts the inner side surface of the side wall and provides an elastic force to the shield can in the first direction to fix the shield can to the bracket, and a connector connected to the elastic portion and contacting the inner side surface of the side wall, the connector extended from the inner side surface of the side wall to the outer side surface of the side wall and back to the inner side surface of the side wall via the two grooves to fix the non-magnetic elastic structure to the bracket.

In various embodiments, the first ground path R1 may be formed by contact between the outer side surface 440a of the shield can 440 and the inner side surface 450a of the bracket 450, and the second ground path R2 may be formed by mutual contact between the shield can 440, the elastic structure 460, and the bracket 450. That is, the shield can and the bracket which are electrically connected to each other at the elastic portion of the elastic structure may define a first ground path including physical contact between the outer surface of the shield can and the inner side surface of the bracket at a first side of the accommodation space, and a second ground path including respective physical contact between the shield can, the elastic structure and the bracket at a second side of the accommodation space.

In various embodiments, the bracket 450 may be electrically connected to a ground layer of the main PCB 340 of the electronic device 301. That is, the electronic device may further include a main printed circuit board including a ground layer, where the bracket of the camera module is electrically connected to the ground layer of the main printed circuit board. Also, the camera module may further include a printed circuit board having an image sensor and the printed circuit board electrically connected to the main printed circuit board.

In various embodiments, the camera module 400 applied to the electronic device 301 may include the lens assembly 410, the PCB 420 including the image sensor 421, the actuator 430 configured to adjust a position of the lens assembly 410, the shield can 440 positioned to cover at least a portion of the actuator 430, the bracket 450 including the accommodation space 451 enclosing the shield can 440 and configured to fix the camera module 400 to the electronic device 301, and the elastic structure 460 of which at least a portion is connected to the bracket 450 to be positioned between the shield can 440 and the bracket 450 and which is configured to generate an elastic force which presses the shield can 440 in one direction in the accommodation space 451, and the shield can 440 may be electrically connected to the bracket 450 by the elastic structure 460.

In various embodiments, a state in which the outer side surface 440a of the shield can 440 is in contact with the inner side surface 450a of the bracket 450 may be maintained by the elastic force of the elastic structure 460.

In various embodiments, the first ground path R1 may be formed by contact between the outer side surface 440a of the shield can 440 and the inner side surface 450a of the bracket 450, and the second ground path R2 may be formed by mutual contact between the shield can 440, the elastic structure 460, and the bracket 450.

In various embodiments, the elastic structure 460 may be formed of a material which is conductive and non-magnetic.

In various embodiments, the electronic device 301 may include the housing 310 configured to form an exterior of the electronic device 301, the support member 320 disposed in an inner space of the housing 310, and the camera module 400 fixedly connected to the support member 320, where the camera module 400 may include the lens assembly 410, the PCB 420 including the image sensor 421, the actuator 430 configured to adjust a position of the lens assembly 410, the shield can 440 positioned to cover at least a portion of the actuator 430, the bracket 450 including the accommodation space 451 enclosing the shield can 440 and configured to fix the camera module 400 to the support member 320, and the elastic structure 460 of which at least a portion is connected to the bracket 450 to be positioned between the shield can 440 and the bracket 450, which is configured to generate an elastic force which presses the shield can 440 in one direction in the accommodation space 451, and which is formed of a conductive and non-magnetic material, the bracket 450 may include at least one side wall 452 forming the accommodation space 451, the elastic structure 460 may be engaged with the side wall 452 of the bracket 450, the shield can 440 may be electrically connected to the bracket 450 by the elastic structure 460, a state in which the outer side surface 440a of the shield can 440 is in contact with the inner side surface 450a of the bracket 450 may be maintained, the first ground path R1 may be formed by contact between the outer side surface 450a of the shield can 440 and the inner side surface 450a of the bracket 450, and the second ground path R2 may be formed by mutual contact between the shield can 440, the elastic structure 460, and the bracket 450.

What is claimed is:

1. An electronic device comprising:
a housing which forms an exterior of the electronic device, the housing defining an inner space;
a support member in the inner space of the housing; and
a camera module fixed to the support member,
wherein the camera module comprises:
a bracket at which the camera module is fixed to the support member, the bracket including an accommodation space defined therein; and
within the accommodation space:
a lens and an actuator which adjusts a position of the lens;
a shield can which covers the actuator; and
an elastic structure which electrically connects the shield can to the bracket, the elastic structure comprising an elastic portion which is between the shield can and the bracket and provides an elastic force to the shield can,
wherein the shield can and the bracket are electrically connected to each other at the elastic portion of the elastic structure.

2. The electronic device of claim 1, wherein
the elastic structure electrically connects the shield can to the bracket at a first side of the accommodation space,
the elastic structure provides the elastic force to the shield can in a direction toward a second side of the accommodation space which is different from the first side, and
the elastic force of the elastic structure maintains an outer side surface of the shield can in contact with an inner side surface of the bracket at the second side of the accommodation space.

3. The electronic device of claim 1, wherein
the bracket comprises a side wall defining the accommodation space, and
the elastic structure is engaged with the side wall of the bracket.

4. The electronic device of claim 3, wherein
the elastic portion is between the shield can and the bracket at an upper side of the side wall,
insertion of the elastic structure into the accommodation space in an insertion direction from a lower side of the side wall to the upper side thereof engages the elastic structure with the side wall of the bracket, and
insertion of the shield can into the accommodation space in the insertion direction electrically connects the shield can to the bracket at the elastic portion of the elastic structure.

5. The electronic device of claim 3, wherein
the elastic portion is between the shield can and the bracket at an upper side of the side wall, and
the bracket further comprises:
a head which protrudes from a lower side of the side wall which is opposite to the upper side, the elastic structure being engaged with the side wall at the head; and
a pair of shoulders respectively extended from opposing ends of the head, the elastic structure which is engaged with the side wall at the head extended along the pair of shoulders.

6. The electronic device of claim 5, wherein the elastic structure comprises:
a support in contact with an outer side surface of the head,
a pair of connectors respectively bent from opposing ends of the support and in a direction toward the accommodation space,
a pair of arm portions which are bent from ends of the pair of connectors, respectively, and
the pair of arm portions in contact with an inner side surface of a respective shoulder.

7. The electronic device of claim 6, wherein the elastic structure further comprises:
a pair of inclined portions inclined from ends of the pair of arm portions, respectively, in the direction toward the accommodation space, and
the pair of inclined portions between the shield can and the bracket and providing the elastic force to the shield can in the direction toward the accommodation space.

8. The electronic device of claim 6, wherein the support has a curved central portion which is in contact with the outer side surface of the head.

9. The electronic device of claim 7, wherein
the elastic structure further comprises a pair of stepped portions stepped from ends of the pair of inclined portions, respectively, in a direction away from the accommodation space,
the bracket further comprises a pair of stepped grooves recessed in the side wall at the upper side of the side wall, the pair of stepped grooves being open to the accommodation space, and
the elastic structure which electrically connects the shield can to the bracket includes the elastic portion providing the elastic force to the shield can in the direction toward the accommodation space together with the pair of stepped portions respectively engaged with the pair of stepped grooves of the bracket.

10. The electronic device of claim 3, wherein the elastic structure comprises:
a clip portion engaged with an outer side surface of the side wall; and
a pair of arm portions extending from the clip portion, the pair of arm portions extending along an inner side surface of the side wall which is opposite to the outer side surface and contacting the inner side surface of the side wall.

11. The electronic device of claim 10, wherein the elastic structure further comprises:
an inclined portion inclined from an end of each of the arm portions, respectively, in a direction toward the accommodation space, and
the inclined portion between the shield can and the bracket and providing the elastic force to the shield can in the direction toward the accommodation space.

12. The electronic device of claim 10, wherein
the elastic portion of the elastic structure is between the shield can and the bracket and provides the elastic force to the shield can in a first direction,
the clip portion comprises:
a first support in contact with the outer side surface of the side wall,
a second support in contact with the inner side surface of the side wall, and
a connector which connects the first support to the second support, and
the clip portion which is unengaged with the side wall includes the first support and the second support spaced apart from each other in the first direction by a distance which is less than a width of the side wall in the first direction.

13. The electronic device of claim 2, wherein the elastic structure is conductive and non-magnetic.

14. The electronic device of claim 2, wherein the shield can and the bracket which are electrically connected to each other at the elastic portion of the elastic structure defines:
a first ground path including physical contact between the outer surface of the shield can and the inner side surface of the bracket at a first side of the accommodation space, and
a second ground path including respective physical contact between the shield can, the elastic structure and the bracket at a second side of the accommodation space.

15. The electronic device of claim 14, further comprising a main printed circuit board including a ground layer,
wherein the bracket of the camera module is electrically connected to the ground layer of the main printed circuit board.

16. The electronic device of claim 1, further comprising a main printed circuit board including a ground layer,
wherein the camera module further comprises a printed circuit board comprising an image sensor, the printed circuit board electrically connected to the main printed circuit board.

17. An electronic device comprising:
a housing which forms an exterior of the electronic device, the housing defining an inner space; and
a camera module which is in the inner space of the housing and fixed to the housing, the camera module comprising:
a bracket at which the camera module is fixed to the housing, the bracket comprising an accommodation space defined by a side wall which surrounds the accommodation space; and
within the accommodation space which is surrounded by the side wall:
a lens assembly including a lens and an actuator which adjusts a position of the lens;
a shield can which covers the actuator and is fixed to the bracket; and
a non-magnetic elastic structure which electrically connects the shield can to the bracket, the non-magnetic elastic structure comprising an elastic portion which is between the shield can and the bracket in a first direction, contacts the side wall and provides an elastic force to the shield can in the first direction to fix the shield can to the bracket.

18. The electronic device of claim 17, wherein
at a first side of the accommodation space, the elastic portion is inclined in a direction away from an inner side surface of the side wall, the elastic portion contacting the inner side surface of the side wall together with contacting an outer side surface of the shield can which faces the inner side surface,
the elastic portion provides the elastic force to the shield can in the first direction toward a second side of the accommodation space which is opposite to the first side, and
the elastic force of the elastic structure maintains the outer side surface of the shield can in contact with the inner side surface of the bracket at the second side of the accommodation space.

19. The electronic device of claim 18, wherein
the elastic portion further comprises a stepped portion extended inclined from an end of the elastic portion in a direction opposite to the first direction,
the bracket further comprises a groove recessed in the side wall and open to the accommodation space, and
the non-magnetic elastic structure comprises the elastic portion which is in contact with both the inner side surface of the side wall and the outer side surface of the shield can together with the stepped portion being in the groove of the bracket.

20. The electronic device of claim 17, wherein
the side wall comprises an inner side surface facing the accommodation space, an outer side surface which is opposite to the inner side surface, and a lower end which connects the outer side surface to the inner side surface, and
the non-magnetic elastic structure further comprises a clip portion extended from the elastic portion, the clip portion extending from the inner side surface of the side wall to the outer side surface of the side wall via the lower surface of the side wall.
